(19) United States
(12) Patent Application Publication
(10) Pub. No.: US 2026/0011588 A1
(43) Pub. Date: Jan. 8, 2026

(54) INFORMATION PROCESSING APPARATUS AND PERFORMANCE MEASUREMENT METHOD

(71) Applicant: Tokyo Electron Limited, Tokyo (JP)

(72) Inventors: Daigo FURUYA, Iwate (JP); Masakazu YAMAMOTO, Iwate (JP); Hiroyuki KARASAWA, Yamanashi (JP); Tadashi ENOMOTO, Iwate (JP)

(21) Appl. No.: 19/255,577

(22) Filed: Jun. 30, 2025

(30) Foreign Application Priority Data
Jul. 8, 2024 (JP) 2024-109802

(51) Int. Cl. H01L 21/67

(52) U.S. Cl. CPC H01L 21/67253; H01L 21/67248

(57) ABSTRACT

An information processing apparatus performs a performance evaluation of a recipe of a substrate processing apparatus performing a film formation processing based on the recipe. The information processing apparatus includes: a prediction unit that predicts a film formation result of the substrate processing apparatus performing the film formation processing based on the recipe; a recipe performance evaluation unit that performs the performance evaluation of the recipe for each evaluation item based on the predicted film formation result of the substrate processing apparatus; and a display control unit that displays the performance evaluation of the recipe for each evaluation item.

### CROSS-REFERENCE TO RELATED APPLICATIONS

This application is based on and claims priority from Japanese Patent Application No. 2024-109802, filed on Jul. 8, 2024, with the Japan Patent Office, the disclosure of which is incorporated herein in its entirety by reference.

### TECHNICAL FIELD

The present disclosure relates to an information processing apparatus and a performance measurement method.

### BACKGROUND

A digital twin technology is known that reproduces the temperature behavior of a substrate processing apparatus, in cyberspace. In the digital twin, a change in the real (physical) space, i.e., the state of the substrate processing apparatus during processing, may be reproduced in the virtual (cyber) space.

### SUMMARY

In one aspect of the present disclosure, an information processing apparatus performs a performance evaluation of a recipe of a substrate processing apparatus performing film formation processing based on the recipe. The information processing apparatus includes: a prediction unit that predicts a film formation result of the substrate processing apparatus performing the film formation processing based on the recipe; a recipe performance evaluation unit that performs the performance evaluation of the recipe for each evaluation item based on the predicted film formation result of the substrate processing apparatus; and a display control unit that displays the performance evaluation of the recipe for each evaluation item.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a configuration diagram of an example of a substrate processing system according to the present embodiment.

FIG. 2 is a hardware configuration diagram of an example of a computer.

FIG. 3 is a functional block diagram illustrating an example of a server apparatus according to the present embodiment.

FIG. 4 is a functional block diagram illustrating an example of a prediction unit according to the present embodiment.

FIG. 5 is a functional block diagram illustrating an example of the prediction unit according to the present embodiment.

FIG. 6 is an explanatory diagram illustrating an example of learning of a machine learning model according to the present embodiment.

FIG. 7 is a flowchart of an example of processing in which the server apparatus according to the present embodiment performs a recipe performance evaluation in a virtual operation of a substrate processing apparatus.

FIG. 8 is an explanatory diagram illustrating an example of evaluation items for recipe performance evaluation.

FIG. 9 is an example of a screen image that displays a recipe performance evaluation for each evaluation item.

FIG. 10 is an explanatory diagram of an example of a film formation stability score.

FIG. 11 is an explanatory diagram of an example of a film formation stability score.

FIG. 12 is a vertical sectional view schematically illustrating a batch apparatus as an example of the substrate processing apparatus according to the present embodiment.

FIG. 13 is a cross-sectional view illustrating the outline of the configuration of a heat treatment furnace.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to drawings.

### System Configuration

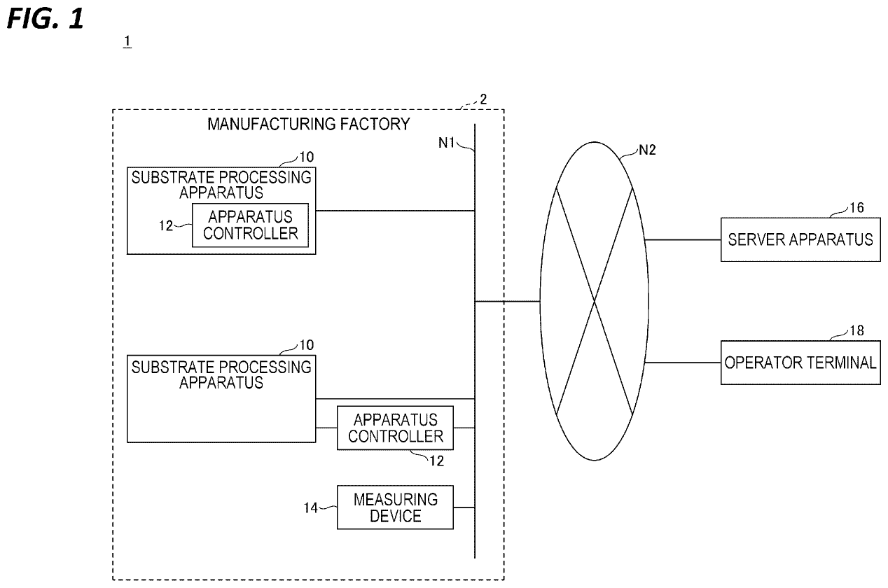

FIG. 1 is a configuration diagram of an example of a substrate processing system 1 according to the present embodiment. The substrate processing system 1 illustrated in FIG. 1 includes a substrate processing apparatus 10, an apparatus controller 12, a measuring device 14, a server apparatus 16 and an operator terminal 18.

The substrate processing apparatus 10, the apparatus controller 12 and the measuring device 14 are installed in a manufacturing factory 2. The server apparatus 16 and the operator terminal 18 may be installed in the manufacturing factory 2, or may be installed outside the manufacturing factory 2. The operator terminal 18 is an information processing terminal (such as a personal computer (PC) or a smartphone) operated by an operator such as a person in charge of equipment or a person in charge of analysis of the substrate processing apparatus 10.

The substrate processing apparatus 10, the apparatus controller 12, the measuring device 14, the server apparatus 16 and the operator terminal 18 are communicatively connected via networks N1 and N2 such as the Internet or a LAN (Local Area Network).

The substrate processing apparatus 10 is an apparatus that performs processing such as film formation processing, etching processing, or ashing processing, and processes, for example, a substrate such as a wafer W. The substrate processing apparatus 10 is, for example, a semiconductor manufacturing apparatus, a heat treatment apparatus, or a film formation apparatus.

The substrate processing apparatus 10 receives, for example, control commands (setting values) based on a recipe, from the apparatus controller 12, and executes a process. The substrate processing apparatus 10 is equipped with a plurality of sensors such as a temperature sensor that measures a temperature and a pressure sensor that measures a pressure.

The apparatus controller 12 receives an instruction for the substrate processing apparatus 10 from the operator. The apparatus controller 12 has a function of a man-machine interface that provides information on the substrate processing apparatus 10 to the operator. The apparatus controller 12 receives sensor data output from a plurality of sensors provided in the substrate processing apparatus 10. The apparatus controller 12 may perform, for example, optimization of setting values of the substrate processing apparatus 10, abnormality detection, or abnormality prediction.

Also, the apparatus controller 12 may also save history information (process logs) of a process such as film formation processing performed by the substrate processing apparatus 10. The apparatus controller 12 may output the process logs to the server apparatus 16 or the operator terminal 18.

The apparatus controller 12 illustrated in FIG. 1 is provided for each substrate processing apparatus 10, but may be provided for a plurality of substrate processing apparatuses 10. The apparatus controller 12 may be provided inside the housing of the substrate processing apparatus 10, or may be provided outside the housing.

The measuring device 14 is a measuring device that measures process results, such as a film thickness measuring device, a sheet resistance measuring device, or a particle measuring device. The measuring device 14 measures, for example, the adhesion state of a film on a substrate such as a wafer W (e.g., the film thickness). Hereinafter, the film thickness included in the process results measured by the measuring device 14 is called an actual film thickness.

The server apparatus 16 may receive and save information on a plurality of substrate processing apparatuses 10 of one or more manufacturing factories 2. For example, the server apparatus 16 may save process logs and process results of the plurality of substrate processing apparatuses 10 of one or more manufacturing factories 2.

The server apparatus 16 may have a man-machine interface function that provides information about the substrate processing apparatus 10, to the operator by using, for example, a Web application. For example, the information about the substrate processing apparatus 10, which is displayed by the server apparatus 16 by using the Web application, includes a recipe performance evaluation based on a virtual operation of the substrate processing apparatus 10 as described below.

The operator terminal 18 may receive and save information on a plurality of substrate processing apparatuses 10 of one or more manufacturing factories 2. For example, the operator terminal 18 may save process logs and process results of the plurality of substrate processing apparatuses 10 of one or more manufacturing factories 2.

The operator terminal 18 may have a man-machine interface function that provides information about the substrate processing apparatus 10, to the operator by using a Web application. For example, the information about the substrate processing apparatus 10, which is displayed by the operator terminal 18 by using the Web application, includes a recipe performance evaluation based on a virtual operation of the substrate processing apparatus 10 as described below.

The apparatus controller 12, the server apparatus 16 and the operator terminal 18 illustrated in FIG. 1 are examples of the information processing apparatus according to the present embodiment. Also, the substrate processing system 1 illustrated in FIG. 1 is an example, and it goes without saying that there are various system configuration examples depending on application or purpose. The classification of apparatuses such as the apparatus controller 12, the server apparatus 16 and the operator terminal 18 in FIG. 1 is an example. For example, various configurations are possible such as a configuration in which at least two of the apparatus controller 12, the server apparatus 16 and the operator terminal 18 are integrated, or a configuration in which the apparatus controller 12, the server apparatus 16 and the operator terminal 18 are further divided.

### Hardware Configuration

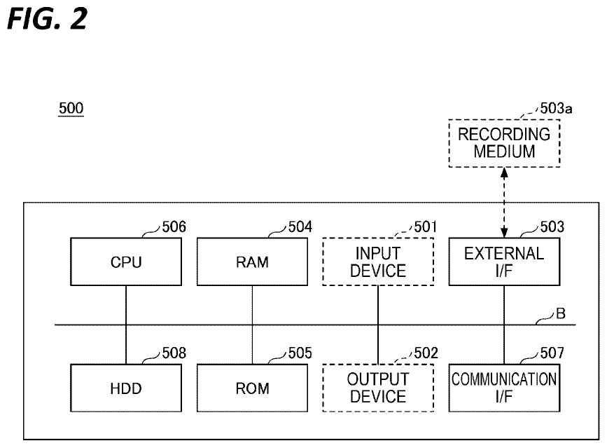

The apparatus controller 12, the server apparatus 16 and the operator terminal 18 illustrated in FIG. 1 may be implemented by, for example, a computer having a hardware configuration illustrated in FIG. 2. FIG. 2 is a hardware configuration diagram of an example of a computer 500.

The computer 500 of FIG. 2 includes, for example, an input device 501, an output device 502, an external interface (I/F) 503, a random access memory (RAM) 504, a read only memory (ROM) 505, a central processing unit (CPU) 506, a communication I/F 507 and a hard disk drive (HDD) 508, which are connected to each other via a bus B. In another configuration, the input device 501 and the output device 502 may be connected and used only when necessary.

The input device 501 is, for example, a keyboard, a mouse, or a touch panel, and is used when the operator inputs an operation signal. The output device 502 is, for example, a display, and displays the results of processing by the computer 500. The communication I/F 507 is an interface that connects the computer 500 to the networks N1 and N2 illustrated in FIG. 1. The HDD 508 is an example of a non-volatile storage device that stores programs or data.

The external I/F 503 is an interface with an external device. The computer 500 may read a recording medium 503a such as a secure digital (SD) memory card via the external I/F 503. The external I/F 503 may also perform writing to the recording medium 503a such as the SD memory card via the external I/F 503.

The ROM 505 is an example of a non-volatile semiconductor memory (storage device) in which programs and data are stored. The RAM 504 is an example of a volatile semiconductor memory (storage device) that temporarily holds programs and data. The CPU 506 is an arithmetic device that reads programs and data from the storage device such as the ROM 505 or the HDD 508, into the RAM 504, and executes processing so as to implement the overall control and functions of the computer 500.

The apparatus controller 12, the server apparatus 16, and the operator terminal 18 of the substrate processing system 1 illustrated in FIG. 1 execute programs on the computer 500 illustrated in FIG. 2 so as to implement various functions.

### Functional Configuration

Hereinafter, descriptions will be made on an example in which the server apparatus 16 is the information processing apparatus that evaluates the performance of a recipe for the substrate processing apparatus 10 performing recipe-based film formation processing. Also, the apparatus controller 12 or the operator terminal 18 may be the information processing apparatus that evaluates the performance of a recipe for the substrate processing apparatus 10 performing recipe-based film formation processing.

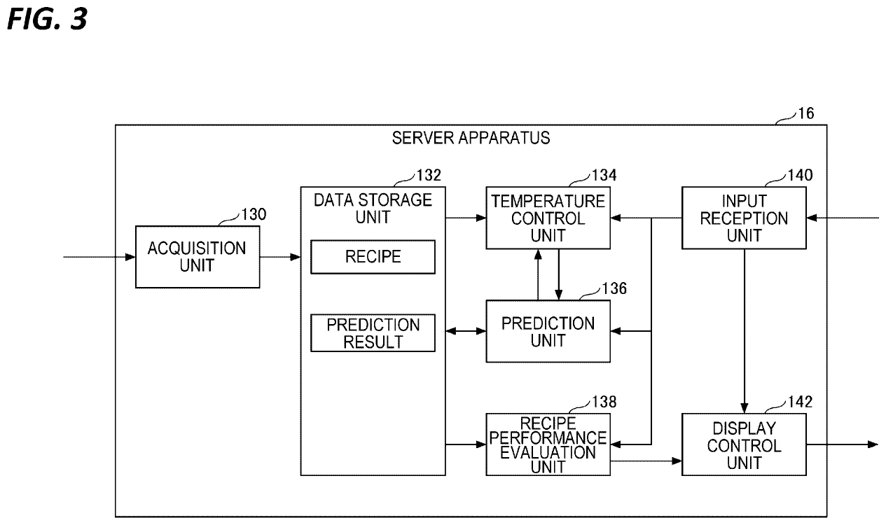

The server apparatus 16 of the substrate processing system 1 according to the present embodiment is implemented by, for example, functional blocks as illustrated in FIG. 3. FIG. 3 is a functional block diagram illustrating an example of the server apparatus 16 according to the present embodiment. Also, in the functional block diagram of FIG. 3, components that are unnecessary for the description of the present embodiment are omitted in the illustration.

The server apparatus 16 in FIG. 3 executes a program for the server apparatus 16 so as to implement an acquisition unit 130, a data storage unit 132, a temperature control unit 134, a prediction unit 136, a recipe performance evaluation unit 138, an input reception unit 140 and a display control unit 142.

The acquisition unit 130 acquires a recipe for the substrate processing apparatus 10. The recipe is information in which control commands (setting values) necessary to allow the substrate processing apparatus 10 to perform film formation processing are set. For example, in the recipe, parameters such as temperature, time and gas flow rate are set. The acquisition unit 130 may accept the input of the recipe for the substrate processing apparatus 10, from the operator, may receive the recipe from a device that saves the recipe for the substrate processing apparatus 10, or may receive the recipe from a device by which the operator creates the recipe for the substrate processing apparatus 10.

The recipe for the substrate processing apparatus 10 acquired by the acquisition unit 130 may include, for example, the initial temperature of each component constituting the substrate processing apparatus 10. Also, the components constituting the substrate processing apparatus 10 may include, for example, a heat insulating cylinder and a boat to be described below. The acquisition unit 130 stores the acquired recipe for the substrate processing apparatus 10, in the data storage unit 132.

The input reception unit 140 receives various operations from the operator. For example, the operations received from the operator include an operation to start an application, various operations for the started application. The input reception unit 140 notifies the temperature control unit 134, the prediction unit 136, the recipe performance evaluation unit 138, and the display control unit 142 of the contents of various operations performed by the operator.

The temperature control unit 134 uses a control algorithm equivalent to that of a temperature controller of the substrate processing apparatus 10. The temperature control unit 134 acquires a set temperature based on the recipe stored in the data storage unit 132. The temperature control unit 134 performs a feedback control on virtual heater power based on the acquired set temperature and the temperature of the temperature sensor predicted by a thermal model 150 of the prediction unit 136 as described below such that the temperature of the wafer W in a processing container approaches the set temperature.

In this way, since the server apparatus 16 uses the temperature control unit 134 with a control algorithm equivalent to that of the actual substrate processing apparatus 10, the temperature control unit 134 and the prediction unit 136 may be linked in order to reproduce the temperature behavior of the substrate processing apparatus 10 in a virtual space. The server apparatus 16 according to the present embodiment utilizes a digital twin technology so as to reproduce the temperature behavior of the substrate processing apparatus 10 performing recipe-based film formation processing, in a virtual space.

The prediction unit 136 predicts the film formation result of the substrate processing apparatus 10 performing film formation processing based on the recipe stored in the data storage unit 132. The prediction unit 136 predicts the temperature of each component constituting the substrate processing apparatus 10 by using the thermal model 150 to be described below. Also, the prediction unit 136 predicts the film formation result of the substrate processing apparatus 10 performing recipe-based film formation processing by using a chemical reaction model 152 or a machine learning model 154 to be described below. The prediction unit 136 stores the film formation result in the virtual operation of the substrate processing apparatus 10 performing recipe-based film formation processing, in the data storage unit 132, as a prediction result.

The recipe performance evaluation unit 138 performs a recipe performance evaluation for each evaluation item to be described below, based on the film formation result (e.g., a predicted film thickness) in the virtual operation of the substrate processing apparatus 10, that is, the prediction result from the prediction unit 136. Details of processing of the recipe performance evaluation unit 138 will be described below. The display control unit 142 displays the recipe performance evaluation evaluated by the recipe performance evaluation unit 138, for each evaluation item, on the output device 502. Details of processing of the display control unit 142 will be described below.

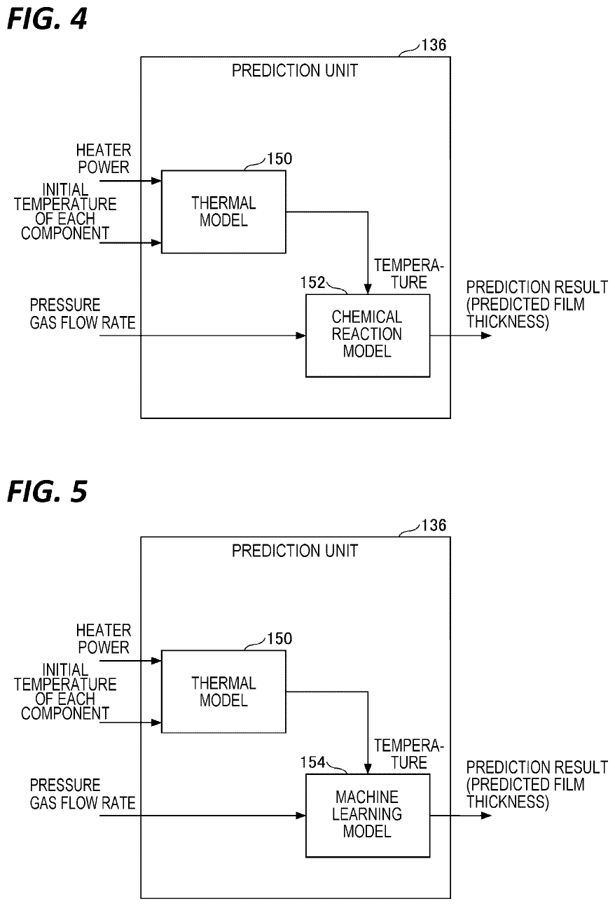

The prediction unit 136 of FIG. 3 is implemented by functional blocks illustrated in, for example, FIG. 4. FIG. 4 is a functional block diagram illustrating an example of the prediction unit 136 according to the present embodiment. Also, in the functional block diagram of FIG. 4, components that are unnecessary for the description of the present embodiment are omitted in the illustration.

The prediction unit 136 of FIG. 4 includes the thermal model 150 and the chemical reaction model 152. The thermal model 150 is a thermal physical model that predicts the temperature of the substrate processing apparatus 10 performing recipe-based film formation processing. The thermal physical model connects thermal relationships between components through physical equations, and simulates the temperature of each component. The thermal model 150 may use, for example, a 1DCAE thermal simulation model.

The thermal model 150 predicts the temperature of each component constituting the substrate processing apparatus 10, from the thermal relationship between components, such as the amount of heat generated by a heater and the heat capacity of each component, based on the virtual heater power output by the temperature control unit 134 and the initial temperature of each component constituting the substrate processing apparatus 10. The thermal model 150 outputs the predicted temperature of each component constituting the substrate processing apparatus 10, to the chemical reaction model 152.

The chemical reaction model 152 is a chemical reaction (film formation reaction) physical model that predicts the film formation result of the substrate processing apparatus 10 performing recipe-based film formation processing. The chemical reaction physical model calculates the film formation rate (e.g., X nm/sec) based on various parameters required for a chemical reaction, such as the temperature of each component constituting the substrate processing apparatus 10, and the pressure and gas flow rate set in the recipe. The prediction unit 136 may output the predicted film thickness as a prediction result by integrating the film formation rates for each period (e.g., 1 sec). Also, the prediction unit 136 may output a plurality of predicted film thicknesses on the wafer W (e.g., two points at the center and the edge).

In this way, the prediction unit 136 in FIG. 4 may combine the thermal model 150 with the chemical reaction model 152, so as to output the predicted film thickness, which is the result of recipe-based film formation processing of the substrate processing apparatus 10, as the prediction result.

The prediction unit 136 in FIG. 3 may be implemented by functional blocks illustrated in FIG. 5. FIG. 5 is a functional block diagram illustrating an example of the prediction unit 136 according to the present embodiment. Also, in the functional block diagram of FIG. 5, components that are unnecessary for the description of the present embodiment are omitted in the illustration.

The prediction unit 136 of FIG. 5 includes the thermal model 150 and the machine learning model 154. The thermal model 150 of FIG. 5 is the same as the thermal model 150 of FIG. 4, and thus the explanation thereof will be omitted. The thermal model 150 outputs the predicted temperature of each component constituting the substrate processing apparatus 10, to the machine learning model 154.

The machine learning model 154 is a chemical reaction virtual machine (VM) that predicts the film formation result of the substrate processing apparatus 10 performing recipe-based film formation processing. The chemical reaction virtual machine may output the predicted film thickness as a prediction result based on various parameters required for prediction, such as the temperature of each component constituting the substrate processing apparatus 10, and the pressure and gas flow rate set in the recipe. The predicted film thickness output by the machine learning model 154 may be a plurality of predicted film thicknesses on the wafer W.

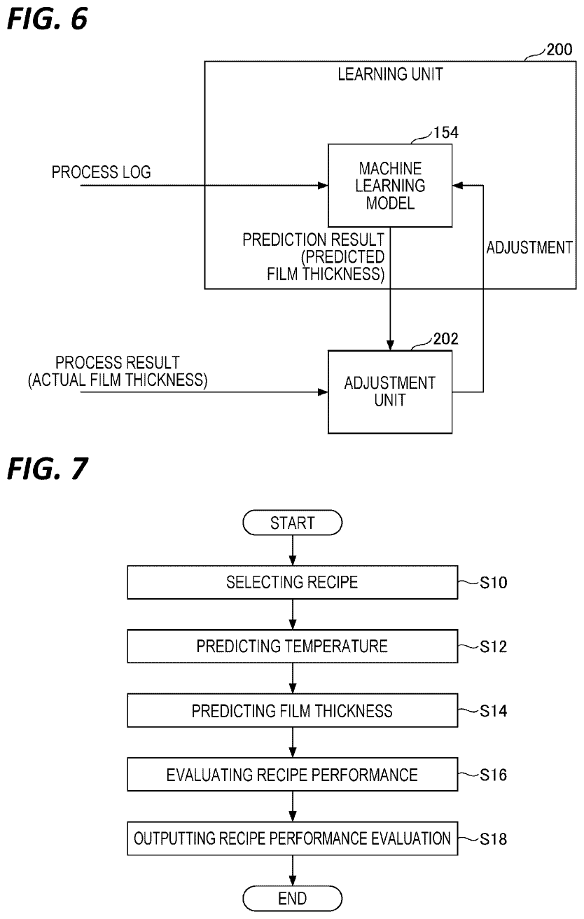

The machine learning model 154 has completed the learning of the relationship between the temperature of each component of the substrate processing apparatus 10 and the recipe, and the film formation result of the substrate processing apparatus 10, as illustrated in, for example, FIG. 6. FIG. 6 is an explanatory diagram illustrating an example of learning of the machine learning model 154 according to the present embodiment. A learning unit 200 in FIG. 6 trains the machine learning model 154 through an existing machine learning method.

The machine learning model 154 has used process logs and process results obtained when recipe-based film formation processing was performed in the reference substrate processing apparatus 10 (hereinafter, referred to as a reference apparatus), so as to complete learning of the relationship between the temperature of the reference apparatus and the recipe, and the film formation result of the reference apparatus, through an existing machine learning method.

The process logs used for machine learning include the temperature (measured temperature) measured by the temperature sensor of the reference apparatus performing recipe-based film formation processing, and the pressure and gas flow rate set in the recipe. The process results used for machine learning include the film formation result of the actual operation of the reference apparatus. The film formation result of the actual operation of the reference apparatus includes the actual film thickness measured by the measuring device 14.

For the machine learning model 154, parameters are adjusted by an adjustment unit 202 such that the film formation result (actual film thickness) of the reference apparatus is output when the measured temperature of the reference apparatus performing recipe-based film formation processing, and the pressure and gas flow rate set in the recipe are input.

The adjustment unit 202 adjusts parameters of the machine learning model 154 so as to reduce a difference between the film formation result (predicted film thickness) of the reference apparatus output by the machine learning model 154, and the film formation result (actual film thickness) of the actual operation of the reference apparatus included in the process results.

Also, the machine learning model 154, which has completed the machine learning by using the process logs and process results obtained when recipe-based film formation processing was performed in the reference apparatus, may be used, as it is, for other substrate processing apparatuses 10 of the same model as the reference apparatus. Based on the learning mechanism illustrated in FIG. 6, the machine learning model 154 that has completed machine learning may correct parameters of the machine learning model 154 by using process logs and process results obtained when recipe-based film formation processing was performed in another substrate processing apparatus 10 of the same model.

Since the parameters of the machine learning model 154 that has completed machine learning are corrected by using process logs and process results obtained when the recipe-based film formation processing was performed in another substrate processing apparatus 10 of the same model, the learning unit 200 may implement the machine learning model 154 corresponding to machine differences. The process logs and process results for correcting the parameters of the machine learning model 154 that has completed machine learning may be for a small number of film formation processing runs.

In this way, according to the prediction unit 136 of FIG. 5, the thermal model 150 and the machine learning model 154 may be combined so as to output the predicted film thickness, which is the result of recipe-based film formation processing of the substrate processing apparatus 10, as a prediction result.

### Processing

The server apparatus 16 performs a recipe performance evaluation in a virtual operation of the substrate processing apparatus 10 in, for example, the processing procedure illustrated in FIG. 7. FIG. 7 is a flowchart of an example of processing in which the server apparatus 16 according to the present embodiment performs a recipe performance evaluation in a virtual operation of the substrate processing apparatus 10.

In the step S10, the server apparatus 16 accepts the selection of a recipe for which performance evaluation is to be performed in the virtual operation of the substrate processing apparatus 10, from the operator.

In the step S12, the prediction unit 136 of the server apparatus 16 predicts the temperature of each component constituting the substrate processing apparatus 10 by using the thermal model 150.

In the step S14, the prediction unit 136 of the server apparatus 16 predicts the film formation result of the substrate processing apparatus 10 performing recipe-based film formation processing by using the chemical reaction model 152 or the machine learning model 154.

In the processing from the steps S10 to S14, a prediction result such as a predicted film thickness may be output through the virtual operation of the substrate processing apparatus 10 performing recipe-based film formation processing.

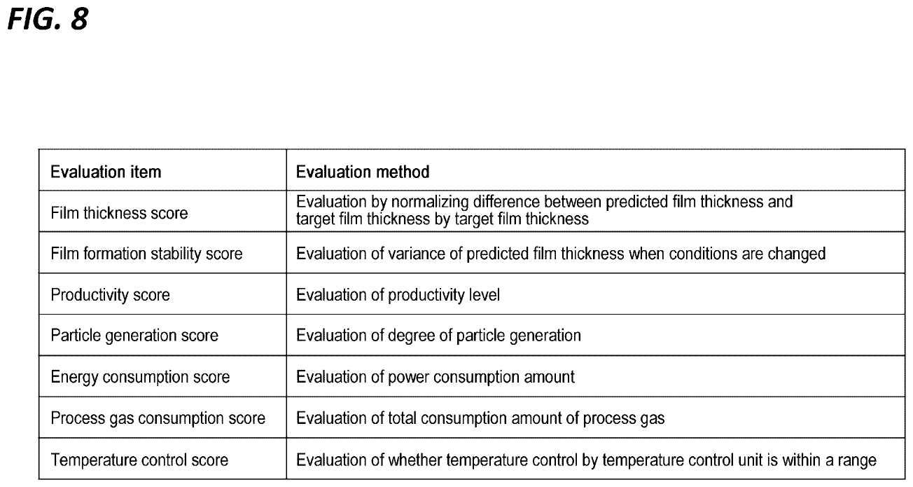

In the step S16, the recipe performance evaluation unit 138 performs a recipe performance evaluation for each evaluation item illustrated in, for example, FIG. 8, based on the prediction result in the virtual operation of the substrate processing apparatus 10, that is, the prediction result from the prediction unit 136.

FIG. 8 is an explanatory diagram illustrating an example of evaluation items for recipe performance evaluation. In FIG. 8, the film thickness score, film formation stability score, productivity score, particle generation score, energy consumption score, process gas consumption score and temperature control score are illustrated as examples of evaluation items for the recipe performance evaluation.

The evaluation items for recipe performance evaluation illustrated in FIG. 8 are merely examples. For example, the evaluation items for recipe performance evaluation may include at least one of the film thickness score, film formation stability score and productivity score. Also, for example, in addition to at least one of the film thickness score, film formation stability score and productivity score, the evaluation items for recipe performance evaluation may further include at least one of the particle generation score, energy consumption score, process gas consumption score and temperature control score.

The film thickness score is an example of a recipe evaluation method that performs an evaluation by normalizing the difference between a predicted film thickness and a target film thickness, with the target film thickness. For example, when the predicted film thickness predicted by the prediction unit 136 is “85 nm,” and the target film thickness of the recipe is “80 nm,” the recipe performance evaluation unit 138 calculates the difference between the predicted film thickness and the target film thickness by the following equation (1).

$$Predicted film thickness {}^{‶} 85 {nm}^{″} - Target film thickness {}^{‶} 80 {nm}^{″} = Difference {}^{‶} 5 {nm}^{″} \qquad ( 1 )$$

The recipe performance evaluation unit 138 normalizes the difference with the target film thickness by the following equation (2).

$$Differemce {}^{‶} 5 {nm}^{″} / Target film thickness {}^{‶} 85 {nm}^{″} = 1 / 16 \qquad ( 2 )$$

The recipe performance evaluation unit 138 converts the normalized value into a score by the following equation (3).

$$100 \times ( 1 - 1 / 16 ) = film thickness score {}^{‶} 93.75 {pt}^{″} \qquad ( 3 )$$

In this way, the recipe performance evaluation unit 138 may quantify the evaluation of the film thickness in the recipe of the substrate processing apparatus 10 based on the calculated film thickness score so as to visualize the performance of the recipe.

The film formation stability score is an example of a recipe evaluation method that evaluates the variance of the predicted film thickness when conditions are changed. For example, the recipe performance evaluation unit 138 evaluates the variance of the predicted film thickness when the initial temperature of each component constituting the substrate processing apparatus 10 is varied. The recipe performance evaluation unit 138 may also evaluate the variance of the predicted film thickness when the gas flow rate is varied. Here, descriptions will be made on an example in which the variance of the predicted film thickness is evaluated when the initial temperature of each component constituting the substrate processing apparatus 10 is varied.

For example, the operator sets the upper and lower limits of the variation range of the initial temperature of each component constituting the substrate processing apparatus 10. The recipe performance evaluation unit 138 calculates the variance of the predicted film thickness when the initial temperature of each component constituting the substrate processing apparatus 10 is varied, within the range of the upper and lower limits of the variation range of the initial temperature of each component constituting the substrate processing apparatus 10. Here, descriptions will be made on an example in which the variance of the predicted film thickness is “0.5 nm.”

The recipe performance evaluation unit 138 normalizes the variance of the predicted film thickness with the target film thickness through the following equation (4), and converts the normalized value into a score.

$$100 \times ( 1 - 0.5 / 80 ) = film formation stability score {}^{‶} 99.4 {pt}^{″} \qquad ( 4 )$$

In this way, the recipe performance evaluation unit 138 may quantify the evaluation for the film formation stability (robustness) in the recipe of the substrate processing apparatus 10 based on the calculated film formation stability score, so as to visualize the performance of the recipe. Also, in the evaluation for the film formation stability (robustness) in the recipe of the substrate processing apparatus 10, “score A” may be given if the variance of the predicted film thickness is within ±0.5% of the target film thickness, and “score B” may be given if the variance of the predicted film thickness is within ±3% of the target film thickness.

The productivity score is an example of a recipe evaluation method that evaluates a productivity level. For example, the recipe performance evaluation unit 138 evaluates the productivity level in terms of the recipe of the substrate processing apparatus 10 performing recipe-based film formation processing. In the evaluation in terms of the recipe, the productivity level is higher when the time required for film formation is shorter.

For example, the recipe performance evaluation unit 138 converts the number of wafers W that can be subjected to film formation per unit time, the time required for one Run, or the time required for one wafer W, into a score. In terms of the recipe, the evaluation of the productivity level may be performed for each substrate processing apparatus 10, or may be performed for each manufacturing factory 2 such as a FAB.

The particle generation score is an example of a recipe evaluation method that evaluates the degree of particle generation. For example, the prediction unit 136 predicts the degree of particle generation. The recipe performance evaluation unit 138 quantifies the probability of particle generation or the number of generated particles. For example, the prediction unit 136 may predict the degree of particle generation by using process logs and process results, through a particle generation model created from the correlation between the recipe, the cumulative film thickness and the particle measurement result obtained by the measuring device 14.

For example, the recipe performance evaluation unit 138 converts the probability of particle generation or the number of generated particles, which is predicted by the prediction unit 136, into a score such that the larger the probability of particle generation or the number of generated particles, the worse the score. The recipe performance evaluation unit 138 may convert the number of particles generated during one Run into a score.

The energy consumption score is an example of a recipe evaluation method that evaluates the power consumption amount. For example, the prediction unit 136 predicts the power consumption amount of the substrate processing apparatus 10. For example, the prediction unit 136 may predict the power consumption amount of the substrate processing apparatus 10 performing recipe-based film formation processing by using process logs and process results, through a power consumption amount model created from the correlation between the recipe, the cumulative film thickness and the power consumption amount of the substrate processing apparatus 10.

For example, the recipe performance evaluation unit 138 may convert the predicted power consumption amount into a score. The recipe performance evaluation unit 138 may convert, for example, the power consumption amount of the substrate processing apparatus 10 for one Run, into a score.

The process gas consumption score is an example of a recipe evaluation method that evaluates the total consumption amount of process gas. For example, the prediction unit 136 predicts the total consumption amount of process gas of the substrate processing apparatus 10. For example, the prediction unit 136 predicts the total consumption amount of process gas of the substrate processing apparatus 10 performing recipe-based film formation processing by using process logs and process results, through a process gas consumption model created from the correlation between the recipe, the cumulative film thickness and the consumption amount of process gas of the substrate processing apparatus 10.

For example, the recipe performance evaluation unit 138 may convert the predicted total consumption amount of process gas, into a score. The recipe performance evaluation unit 138 may convert, for example, the total consumption amount of process gas of the substrate processing apparatus 10 for one Run, into a score.

The temperature control score is an example of a recipe evaluation method that evaluates temperature control. For example, the prediction unit 136 predicts whether the temperature control on the substrate processing apparatus 10 is within a range. For example, the prediction unit 136 predicts whether the temperature control performed by the temperature control unit 134 on the substrate processing apparatus 10 performing recipe-based film formation processing is within the range.

For example, the recipe performance evaluation unit 138 may output a prediction as to whether the temperature control performed by the temperature control unit 134 on the substrate processing apparatus 10 performing recipe-based film formation processing is within a range, as, for example, Safe/Out, or may convert the prediction into a score.

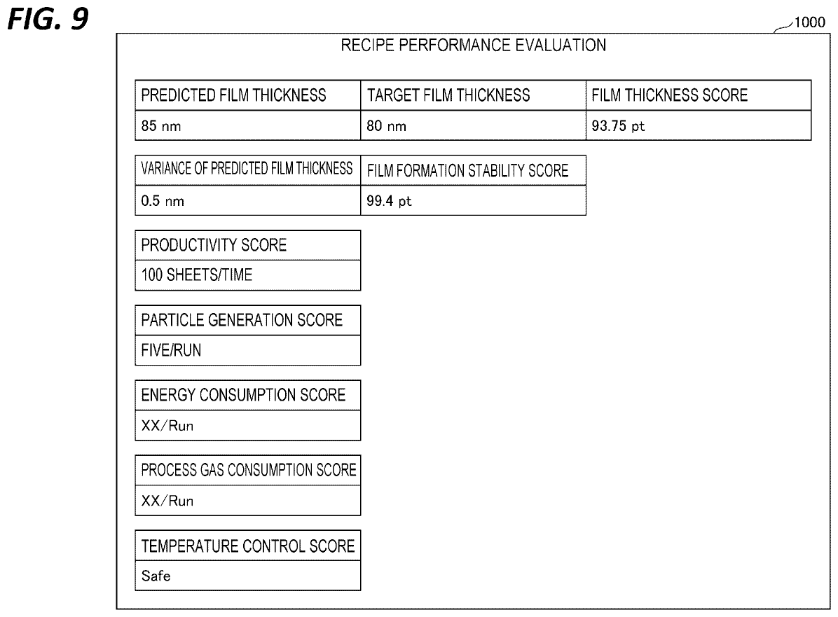

Referring back to FIG. 7, in the step S18, the display control unit 142 displays the recipe performance evaluation evaluated by the recipe performance evaluation unit 138, for each evaluation item, on, for example, the output device 502 as illustrated in FIG. 9.

FIG. 9 is an example of a screen image that displays a recipe performance evaluation for each evaluation item. A screen 1000 of FIG. 9 illustrates an example of evaluation items for recipe performance evaluation illustrated in FIG. 8. The screen 1000 of FIG. 9 displays (visualizes) the recipe performance evaluation for each evaluation item, making it easy for the operator to grasp the performance of the recipe.

For example, the evaluation items illustrated in FIG. 8 have different priorities depending on the operator. An operator who wants to reduce the environmental load places importance on the energy consumption score and the process gas consumption score of FIG. 8. Also, an operator who wants to improve productivity places importance on the productivity score of FIG. 8. By displaying the screen 1000 of FIG. 9, the operator may perform the recipe performance evaluation with an emphasis on the evaluation items that the operator wants to prioritize.

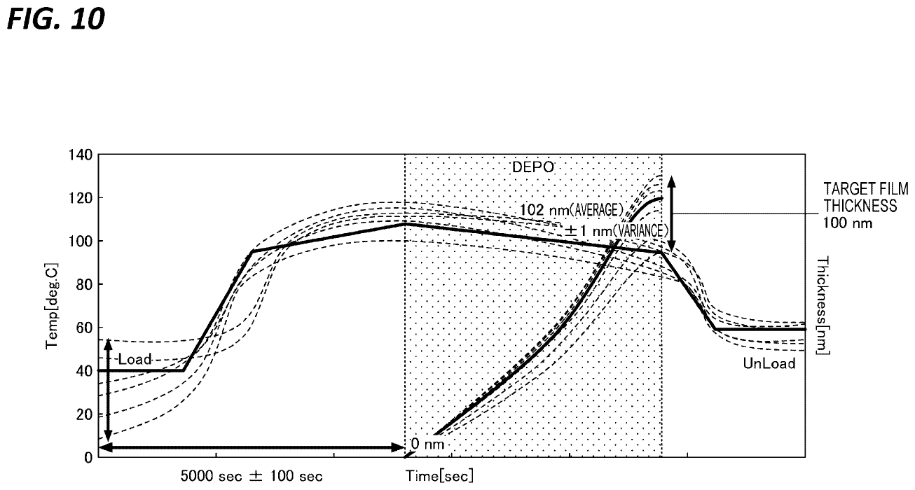

FIG. 10 is an explanatory diagram of an example of a film formation stability score. In the graph diagram of FIG. 10, the horizontal axis indicates time. Also, the graph diagram of FIG. 10 illustrates a temporal change of the temperature of the wafer W, and a temporal change of the predicted film thickness of the wafer W. Since the graph diagram of FIG. 10 illustrates a state where the initial temperature of each component constituting the substrate processing apparatus 10 is varied, there are deviations in the temporal change of the temperature of the wafer W, and the temporal change of the predicted film thickness of the wafer W.

As illustrated in FIG. 10, the server apparatus 16 according to the present embodiment may create a recipe for obtaining a desired target film thickness by calculating the average and variance of predicted film thicknesses when the initial temperature of each component constituting the substrate processing apparatus 10 is varied. Also, the server apparatus 16 according to the present embodiment may quantify the evaluation of the film formation stability (robustness) in the recipe of the substrate processing apparatus 10 so as to visualize the performance of the recipe.

Also, the server apparatus 16 according to the present embodiment may display the graph diagram of FIG. 10 on the output device 502 to allow the operator to check the diagram. By referring to the graph diagram of FIG. 10, the operator may know the effect of an apparatus state at the starting point of time of the recipe (such as the initial temperature of each component constituting the substrate processing apparatus 10) on film formation processing. Also, by referring to the graph diagram of FIG. 10, the operator may know the time required to dissipate heat to a level that does not affect the next Run. Since the operator can know the standby time required between Runs, it is possible to shorten the interval time between Runs.

Also, in the graph diagram of FIG. 10, a recipe with a small difference between the target film thickness and the predicted film thickness, and a low variance of the predicted film thickness becomes a recipe by which a desired film thickness is easy to obtain, and the film formation stability becomes high.

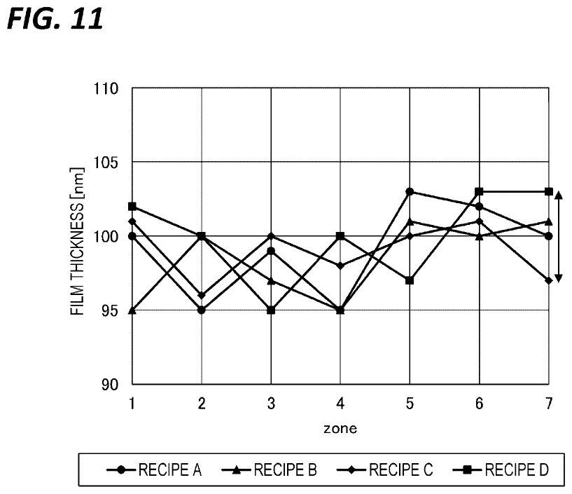

Also, as illustrated in FIG. 11, the server apparatus 16 according to the present embodiment may display the predicted film thickness for each recipe of the substrate processing apparatus 10, as a graph diagram. FIG. 11 is an explanatory diagram of an example of a film formation stability score. In the graph diagram of FIG. 11, the horizontal axis indicates a zone. The zone is a unit area that can be heated and controlled by a heater.

As illustrated in FIG. 11, the server apparatus 16 according to the present embodiment may calculate the variation state (variance) of the film formation result, for the recipe in which the initial temperature of each component constituting the substrate processing apparatus 10 is varied, and may quantify the evaluation for the film formation stability (robustness) in the recipe of the substrate processing apparatus 10 so as to visualize the performance of the recipe.

The server apparatus 16 according to the present embodiment displays (visualizes) the recipe performance evaluation for each evaluation item, making it easy for the operator to grasp the performance of the recipe, to compare recipes with each other and to grasp room for improvement of the recipe. According to the server apparatus 16 according to the present embodiment, the recipe performance evaluation of the substrate processing apparatus 10 does not rely on individual expertise, and even an operator without advanced specialized knowledge may easily perform the recipe performance evaluation of the substrate processing apparatus 10.

Also, the server apparatus 16 according to the present embodiment makes it possible to circulate the operations of evaluating the performance of a created recipe, visualizing the recipe performance, modifying the recipe based on the recipe performance evaluation, and evaluating the performance of the modified recipe. In this way, according to the present embodiment, it is possible to provide a technique of improving the ease of recipe performance evaluation of the substrate processing apparatus 10.

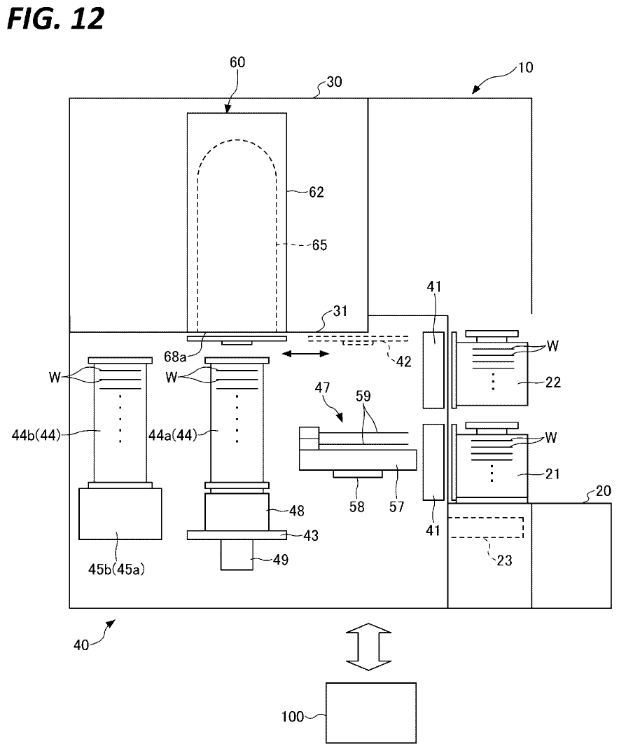

FIG. 12 is a vertical sectional view schematically illustrating a batch apparatus as an example of the substrate processing apparatus 10 according to the present embodiment. The substrate processing apparatus 10 includes a vertical heat treatment furnace 60. The substrate processing apparatus 10 holds and accommodates wafers W in a boat at predetermined intervals along the vertical direction, and performs various heat treatments such as oxidation, diffusion, and reduced-pressure CVD, on the wafers W. The substrate processing apparatus 10 supplies a process gas into a processing container 65, thereby forming a film on the surface of the wafer W provided in the processing container 65.

The substrate processing apparatus 10 of FIG. 1 includes a stage (load port) 20, a housing 30 and an apparatus controller 100. The housing 30 includes a loading area (work area) 40 and the heat treatment furnace 60.

The loading area 40 is formed at the lower side within the housing 30. The heat treatment furnace 60 is provided above the loading area 40 within the housing 30. Also, a base plate 31 is provided between the loading area 40 and the heat treatment furnace 60.

The stage (load port) 20 allows the wafers W to be loaded and unloaded into/from the housing 30. On the stage (load port) 20, storage containers 21 and 22 are placed. Each of the storage containers 21 and 22 is a sealed storage container (FOUP) that has a lid (not illustrated) detachably provided on the front side thereof, and is capable of storing a plurality of wafers W (for example, about 25 wafers) at predetermined intervals.

Also, an alignment device (aligner) 23 may be provided below the stage 20 in order to align notched portions (e.g., notches) formed on the outer peripheries of the wafers W transferred by a transfer mechanism 47, in one direction.

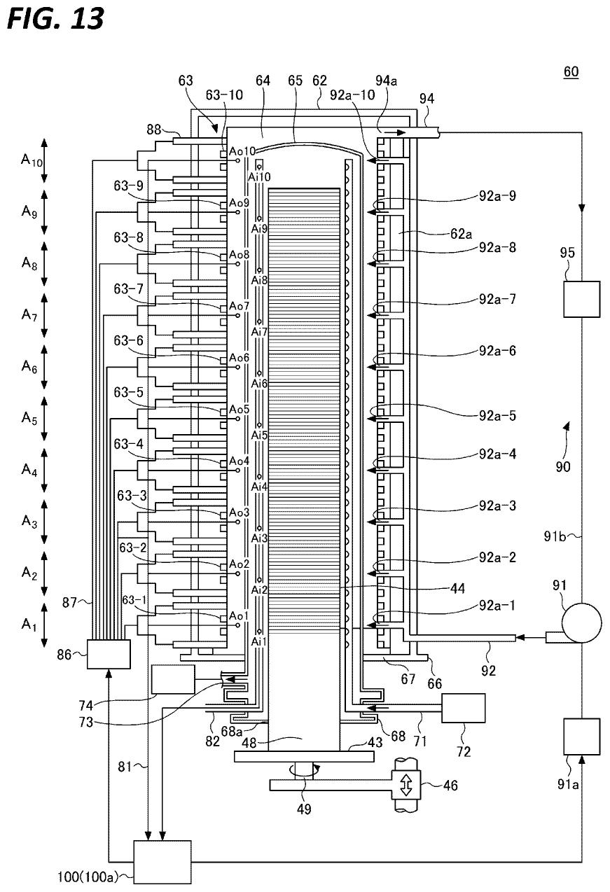

In the loading area (work area) 40, the wafers W are transferred between the storage containers 21 and 22 and a boat 44, the boat 44 is loaded into the processing container 65, and the boat 44 is unloaded from the processing container 65. The loading area 40 is provided with a door mechanism 41, a shutter mechanism 42, a lid body 43, the boat 44, a base 45a, a base 45b, a lifting mechanism 46 of FIG. 13 and the transfer mechanism 47.

The door mechanism 41 is configured to remove the lids of the storage containers 21 and 22, and to open the storage containers 21 and 22 such that the inside of the storage containers 21 and 22 communicates with the inside of the loading area 40.

The shutter mechanism 42 is provided above the loading area 40. The shutter mechanism 42 is provided to cover (or block) a furnace opening 68a in order to suppress or prevent the release of heat in the high-temperature furnace to the loading area 40 via the furnace opening 68a when the lid body 43 is open.

The lid body 43 has a heat insulating cylinder 48 and a rotating mechanism 49. The heat insulating cylinder 48 is provided on the lid body 43. The heat insulating cylinder 48 is configured to prevent the boat 44 from being cooled due to heat-transfer to the lid body 43 side, and to keep the boat 44 warm. The rotating mechanism 49 is attached to the bottom of the lid body 43. The rotating mechanism 49 is configured to rotate the boat 44. The rotation shaft of the rotating mechanism 49 passes through the lid body 43 in an airtight manner, and is provided to rotate a rotary table disposed on the lid body 43.

The lifting mechanism 46 drives the lid body 43 to raise and lower the lid body 43 when the boat 44 is loaded or unloaded into/from the processing container 65 from/into the loading area 40. Then, when the lid body 43 that has been raised by the lifting mechanism 46 is loaded into the processing container 65, the lid body 43 is provided to abut against the furnace opening 68a and to seal the furnace opening 68a.

The boat 44 placed on the lid body 43 may hold the wafers W in the processing container 65 such that the wafers W are rotatable in the horizontal plane. Also, the substrate processing apparatus 10 may include a plurality of boats 44. The loading area 40 is provided with boats 44a and 44b.

In the loading area 40, the base 45a, the base 45b and a boat transfer mechanism are provided. The bases 45a and 45b are stages to which the boats 44a and 44b are transferred, respectively, from the lid body 43. The boat transfer mechanism is configured to transfer the boat 44a or 44b from the lid body 43 to the base 45a or 45b.

The boats 44a and 44b are made of, for example, quartz. In the boats 44a and 44b, wafers W having a large diameter, e.g., a diameter of 300 mm, in a horizontal state, are mounted in the vertical direction at predetermined intervals (pitch widths). In the boats 44a and 44b, a plurality of supports (e.g., three supports) is provided between the top plate and the bottom plate. The supports are provided with claws for holding the wafers W. Also, the boats 44a and 44b may be appropriately provided with auxiliary columns together with the supports.

The transfer mechanism 47 is configured to transfer the wafers W between the storage container 21 or 22 and the boat 44a or 44b. The transfer mechanism 47 includes a base 57, a lifting arm 58 and a plurality of forks (transfer plates) 59. The base 57 is provided so as to be movable up and down and rotatable. The lifting arm 58 is provided so as to be vertically movable (liftable) by a ball screw, etc. The base 57 is provided on the lifting arm 58 so as to be horizontally rotatable.

FIG. 13 is a cross-sectional view illustrating the outline of the configuration of the heat treatment furnace. The heat treatment furnace 60 of FIG. 13 is an example of a vertical furnace for accommodating a plurality of thin-plate disk-shaped wafers W and performing a predetermined heat treatment. The heat treatment furnace 60 includes a jacket 62, a heater 63, a space 64 and the processing container 65.

The processing container 65 is configured to store the wafers W held in the boat 44 and to perform heat treatment. The processing container 65 is made of, for example, quartz, and has a vertically long shape. The processing container 65 is supported by a base plate 66 via a manifold 68 at the bottom. Gas is supplied from the manifold 68 to the processing container 65 via an injector 71. The injector 71 supplies gas from a blowing portion (holes) into the processing container 65. The injector 71 is connected to a gas supply source 72. Also, the gas supplied to the processing container 65 is exhausted from an exhaust system 74 provided with a vacuum pump capable of reduced-pressure control via an exhaust port 73.

The lid body 43 closes the furnace opening 68a at the lower portion of the manifold 68 when the boat 44 is loaded into the processing container 65. The lid body 43 is provided so as to be movable up and down by the lifting mechanism 46. The heat insulating cylinder 48 is placed on the top of the lid body 43. The boat 44 in which a large number of wafers W are mounted at predetermined intervals in the vertical direction is provided on the top of the heat insulating cylinder 48.

The jacket 62 is provided to cover the periphery of the processing container 65, and defines the space 64 around the processing container 65. The jacket 62 has a cylindrical shape like the processing container 65. The jacket 62 is supported by the base plate 66. A heat insulating material 62a including, for example, glass wool may be provided inside the jacket 62 and outside the space 64.

The heater 63 is provided to cover the periphery of the processing container 65. For example, the heater 63 is provided inside the jacket 62 and outside the space 64. The heater 63 heats the processing container 65, and heats the wafers W held in the boat 44, that is, the wafers W in the processing container 65. The heater 63 functions as a heating portion that heats the wafers W.

Also, the heater 63 includes, for example, a heating resistor such as carbon wire, and controls the temperature of gas flowing inside the space 64. Thus, it is possible to perform a control such that the inside of the processing container 65 is heated to a predetermined temperature (for example, 50 to 1200° C.).

The space 64 and the space in the processing container 65 are divided into a plurality of unit areas along the vertical direction, for example, ten unit areas A1, A2, A3, A4, A5, A6, A7, A8, A9, and A10. The heater 63 is divided along the vertical direction into 63-1, 63-2, 63-3, 63-4, 63-5, 63-6, 63-7, 63-8, 63-9 and 63-10 each corresponding to one of the unit areas. Each of the heaters 63-1 to 63-10 is configured to independently control heating corresponding to each of the unit areas A1 to A10 by the output (heater power) of a heater output unit 86 including, for example, a thyristor. The heaters 63-1 to 63-10 are examples of heating elements.

Each of the measurement signals from temperature sensors Ao1 to Ao10 is input to the apparatus controller 100 via a line 81. Each of the measurement signals from temperature sensors Ai1 to Ai10 is input to the apparatus controller 100 via a line 82. The apparatus controller 100 to which the measurement signals are input controls heater power to be output by the heater output unit 86 based on the set temperature. The heater output unit 86 supplies heater power to each of the heaters 63-1 to 63-10 via a heater output line 87 and a heater terminal 88.

Also, the heat treatment furnace 60 may include a cooling mechanism 90 for cooling the processing container 65. The cooling mechanism 90 includes, for example, a blower 91, a blower pipe 92 and an exhaust pipe 94.

The substrate processing system 1 according to the present disclosure is not limited to the configuration illustrated in FIG. 1, and needless to say, there are various system configuration examples depending on the application or purpose. The substrate processing apparatus 10 of the present disclosure may be applied to any of a single-wafer apparatus that processes substrates one by one, a batch apparatus that processes a plurality of substrates at once, and a semi-batch apparatus.

According to the present disclosure, it is possible to provide a technology of improving the ease of recipe performance evaluation of the substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
prediction circuitry configured to predict a film formation result of a substrate processing apparatus performing a film formation processing based on a recipe;
recipe performance evaluation circuitry configured to perform a performance evaluation of the recipe for each evaluation item based on the film formation result of the substrate processing apparatus predicted by the prediction circuitry; and
display control circuitry configured to display the performance evaluation of the recipe for each evaluation item.

2. The information processing apparatus according to claim 1, wherein the prediction circuitry include a thermal physical model that predicts a temperature of the substrate processing apparatus performing the film formation processing based on the recipe, and a chemical reaction physical model that predicts the film formation result of the substrate processing apparatus performing the film formation processing based on the recipe, and
the chemical reaction physical model predicts the film formation result of the substrate processing apparatus based on the temperature of the substrate processing apparatus predicted by the thermal physical model and the recipe.

3. The information processing apparatus according to claim 1, wherein the prediction circuitry include a thermal physical model that predicts a temperature of the substrate processing apparatus performing the film formation processing based on the recipe, and a chemical reaction machine learning model that predicts the film formation result of the substrate processing apparatus performing the film formation processing based on the recipe, and
the chemical reaction machine learning model has been trained on a relationship between the temperature of the substrate processing apparatus and the recipe, and the film formation result of the substrate processing apparatus, and are configured to predict the film formation result of the substrate processing apparatus based on the temperature of the substrate processing apparatus predicted by the thermal physical model and the recipe.

4. The information processing apparatus according to claim 1, wherein the recipe performance evaluation circuitry are configured to perform the performance evaluation on at least one of film thickness, film formation stability, and productivity, as the evaluation item, based on the film formation result of the substrate processing apparatus predicted by the prediction circuitry.

5. The information processing apparatus according to claim 4, wherein the recipe performance evaluation circuitry are further configured to perform the performance evaluation on at least one of particle generation, energy consumption, process gas consumption and temperature control, as the evaluation item, based on the film formation result of the substrate processing apparatus predicted by the prediction circuitry.

6. The information processing apparatus according to claim 4, wherein the recipe performance evaluation circuitry are configured to perform the performance evaluation of the film thickness through an evaluation method that normalizes a difference between the predicted film thickness predicted by the prediction circuitry and a target film thickness of the recipe, with the target film thickness.

7. The information processing apparatus according to claim 4, wherein the recipe performance evaluation circuitry are configured to perform the performance evaluation of the film formation stability through an evaluation method that evaluates a variance of the film thickness predicted by the prediction circuitry when conditions are changed.

8. A performance evaluation method comprising:
predicting a film formation result of a substrate processing apparatus performing a film formation processing based on a recipe;
performing a performance evaluation of the recipe for each evaluation item based the film formation result of the substrate processing apparatus predicted in the predicting; and
displaying the performance evaluation of the recipe for each evaluation item.
